(19) United States
(12) Patent Application Publication
(10) Pub. No.: US 2012/0306096 A1
(43) Pub. Date: Dec. 6, 2012

(54) METHOD AND MODEL OF CARBON NANOTUBE BASED THROUGH SILICON VIAS (TSV) FOR RF APPLICATIONS

(75) Inventors: Bruce Kim, Tuscaloosa, AL (US); Anurag Gupta, Tuscaloosa, AL (US); Sukeshwar Kannan, Tuscaloosa, AL (US); Falah Mohammed, Tuscaloosa, AL (US); Byoungchul Ahn, Daegu (KR)

(73) Assignee: THE BOARD OF TRUSTEES OF THE UNIVERSITY OF ALABAMA, Tuscaloosa, AL (US)

(21) Appl. No.: 13/483,270

(22) Filed: May 30, 2012

Related U.S. Application Data
(60) Provisional application No. 61/491,306, filed on May 30, 2011.

(51) Int. Cl. H01L 23/48; B82Y 99/00

(52) U.S. Cl. 257/774; 257/E23.011; 977/742

(57) ABSTRACT

A carbon nanotube (CNT) through silicon via (TSV) for three-dimensional (3D) substrate interconnects is described. TSV technologies provide for high performance and high density 3D packages. The CNT-based TSVs provide for integration of analog, RF and mixed-signal integrated circuits. CNT-based TSV provides superior electrical characteristics as compared to conventional TVs filled with conductive metals.

### CROSS-REFERENCE TO RELATED APPLICATION

This application claims priority to U.S. Provisional Patent Application No. 61/491,306, filed May 30, 2011, and entitled “Method and Model of Carbon Nanotube Based Through Silicon Vias (TSV) for RF Applications,” which is incorporated herein by reference in its entirety.

### BACKGROUND

Packaging technologies for integrated circuits are continuously being developed to satisfy the demand toward miniaturization and mounting reliability. For example, high density through silicon via (TSV) is an emerging technique for fabricating three-dimensional (3D) large-scale integration (LSI) packages. The evolving interconnect technologies have been a major factor which has complemented the 3D integration scheme, and has contributed in a significant way in realization of high density and multifunctional microelectronics. Three dimensional TSV interconnects have shown great promise for overcoming fundamental bottlenecks which plague conventional interconnects. For example, three dimensional TSV interconnects provide a physical size reduction, which saves valuable real estate, and a shorter interconnect length, which reduces local and global delays. They also provide for faster operating speeds by improving clock rates, lower power consumption, and reduce the need for large input/output drivers. TSV interconnects may also enable the integration of heterogeneous technologies such as digital, analog, RF, MEMS, etc. onto one single system.

With the aforementioned design and fabrication considerations, the material used as filler greatly affects TSV interconnect performance. Conventionally, filler materials such as Copper (Cu), Tungsten (W), Poly-Silicon, Gold (Au), and conductive polymer pastes have been utilized. However, each has limitations that present challenges to fabrication, packaging and testing. For example, Cu has a high electrical conductivity, a well established Electrochemical deposition (ECD) process, and good thermal characteristics. However, Cu has limitations in achieving Physical Vapor Deposition (PVD) seed layer deposition for ECD, electromigration, and increasing resistivity under combined effects of scattering and presence of highly diffusive barrier layer with physical scaling making it a difficult choice for high aspect ratio via. Similarly, W, which is best suited to fill small via with high aspect ratios and at temperatures as low as 200° C., but W cannot be used for a large via and it has conductivity lower than Cu. Likewise with Poly-Silicon, Au etc. there are issues which make them unsuitable choices as interconnect filler material.

### SUMMARY

Single-walled carbon nanotube (SW-CNT) bundles may be used as an interconnect material as they overcome traditional bottlenecks associated with conventional TSV interconnects. SW-CNT bundles exhibit unique electrical, thermal and mechanical characteristics which can be exploited to fabricate improved TSV interconnects for, e.g., 3D packaging applications.

This summary is provided to introduce a selection of concepts in a simplified form that are further described below in the detailed description. This summary is not intended to identify key features or essential features of the claimed subject matter, nor is it intended to be used to limit the scope of the claimed subject matter.

### BRIEF DESCRIPTION OF THE DRAWINGS

The foregoing summary, as well as the following detailed description of illustrative embodiments, is better understood when read in conjunction with the appended drawings. For the purpose of illustrating the embodiments, there is shown in the drawings example constructions of the embodiments; however, the embodiments are not limited to the specific methods and instrumentalities disclosed. In the drawings:

FIG. 1A illustrates a schematic of a CNT-TSV for RF applications;

FIG. 1B illustrates an equivalent circuit model of the schematic of FIG. 1A;

FIGS. 2 illustrates an equivalent electrical model of a single walled-carbon nanotube (SW-CNT);

FIG. 3 illustrates equivalent electrical model of a SW-CNT TSV;

FIG. 4 illustrates S11 and S21 parameters of SW-CNT TSV vs. a number of CNTs in one bundle;

FIG. 5 illustrates S11 and S21 parameters of both Cu-TSV and SW-CNT TSV vs. change in via dimensions;

FIGS. 6A-6B illustrates S11 and S21 for low-performance CNT-TSV;

FIGS. 6C-6D illustrates S11 and S21 for high-performance CNT-TSV;

FIGS. 7A-7B illustrate Eye diagrams for low-performance CNT-TSV and high-performance CNT-TSV, respectively; and

FIG. 8 illustrates Time Domain Reflectometry (TDR) waveforms of high- and low-performance CNT-TSV.

### DETAILED DESCRIPTION

Introduction

To model a single walled-carbon nanotube (SW-CNT) based structure, the equivalent electrical models of both TSV and SW-CNT may be integrated together to obtain an equivalent electrical model of TSV with SW-CNT as the interconnect material. As will be described below, the circuit models are based on solving Schrodinger's equation to calculate quantum capacitance, kinetic inductance and resistances. As described below, after achieving the integrated electrical model for the TSV with SW-CNT, the signal integrity of the model may be determined. However, before proceeding with the discussion of the integrated model and the assumptions made, the parasitic quantities which are unique to nanostructure materials (e.g., SW-CNTs) will be introduced.

CNT Quantum Resistance

The quantum resistance is the minimum resistance of a quantum wire neglecting any scatterings at the contacts or along the nanowire. According to the theory of Landauer-Buttiker, the maximum conductance that can be achieved by SW-CNT (assuming perfect contacts) is 4e²/h=155 μS, which takes into account the spin degeneracy and sub-lattice degeneracy of electrons in graphene. It is to be noted that this value of conductance holds for ballistic SW-CNT where the mean free path of electrons (A) (typically>1 μm) is greater than length of CNT. When the length of CNT exceeds the typical mean free path, additional ohmic resistance due to scattering, which scales with length, has to be taken into consideration and is given by (h/4e²)L/λ, with L being the length of CNT.

CNT Kinetic inductance

The total energy associated with electric current is:

$$E = {\int }_{all space}^{ } \frac{1}{2} μ {H}^{2} d V + {\int }_{conductor}^{ } \frac{1}{2} {nmv}^{2} d V \qquad ( i )$$

where μ is permeability, H is the magnetizing force, and m, v and n are mass, speed, and density of charged particles, respectively. In bulk wires, the energy stored in the magnetic field is quite large so that the second integral can be safely neglected. However, for a one dimensional (1D) structure such as CNTs, kinetic inductance is taken into account as per certain conditions. In particular, it contributes significantly in CNTs under ballistic transport condition when length of nanotube (L) is less than the mean free path (λ). This is so because this term has been derived considering no voltage drop across CNT, which is only valid under ballistic transport condition. When the length of CNT becomes larger, including kinetic inductance can induce significant errors in calculation. Also, studies on high frequency characteristics have shown that up to 10 GHz frequency there are no large kinetic inductance effects observed.

CNT Quantum Capacitance

Quantum capacitance represents stored energy in a carbon nanotube which carries current. It can be expressed as C_{Q}=2e²/(hv_{F}), where, v_{F} is the Fermi velocity of CNT (≈8×10⁵ m/s), h is the Planck's constant and e is the electronic charge. The CNT may have 4 conducting channels in parallel, thus the effective capacitance per CNT is 4C_{Q}, which is taken in series with electrostatic capacitance as same charge resides on both of them.

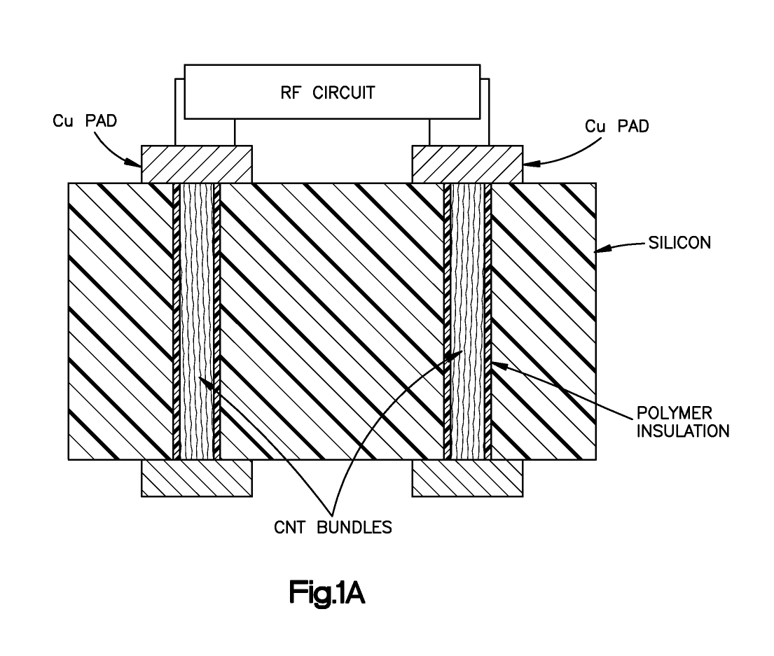

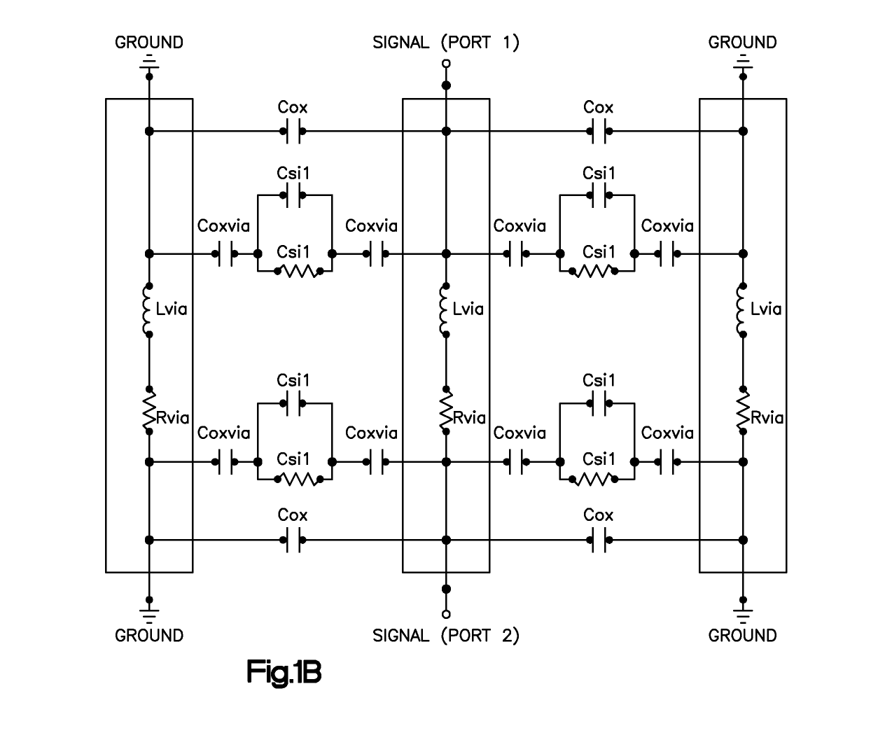

With reference to the above, the integrated electrical model of TSV and SW-CNT bundles will now be described. In some implementations, where the design may be used in high frequency applications, such as RF applications, the TSV may be arranged in a coplanar waveguide fashion to facilitate power measurements at the frequency range of 2 GHz to 20 GHz. With reference to FIG. 1A, there is shown a schematic 100 of a CNT-TSV for RF applications. In FIG. 1A, the substrate 102 may be made of silicon having CNT bundles 106 passing therethrough. Metallic pads (Cu) 104A and 104b may be disposed on an upper and/or lower surface of the substrate 102 and in electrical communication with the CNT bundles 106. A height of TSV (h_{TSV}) may be 90 μm, and a diameter of TSV (D_{TSV}) may be 75 μm. An SiO₂ layer (polymer insulation 108) may be formed between every via and the silicon to act as an insulating layer. The thickness of SiO₂ around the via (tₒₓ) may be 0.1 μm. A distance between two TSV (d) may be 100 μm. The components 102-108 may be part of a package that communicates with an, e.g., RF circuit 110.

In some implementations, CNT-based 3D TSV may be used in 60 GHz applications such as military communications, high-frequency acoustics and other high-end wireless applications. The schematic depicting TSV filled with SW-CNT bundles is shown in FIG. 1A. The equivalent circuit model is developed by considering TSVs arranged in a coplanar waveguide fashion to ensure effective microwave measurements as depicted in FIG. 1B. Cross talk parameters may be appropriately modeled by considering various parasitics associated with CNTs, via geometry and substrate. For high frequency, the equivalent model shown in FIG. 1B has to be modified to take substrate behavior into consideration. The via parasitics, shown in FIG. 1B, may be calculated as follows.

Capacitance of silicon between via:

$${C}_{sil} = \frac{{ɛ}_{0} {ɛ}_{r} A}{d} ,$$

where ε₀=8.854×10¹², εᵣ=3.9 for silicon, and A=πr_{TSV}h_{TSV}=1.06×10⁻⁸ m². Thus, C_{Sil}=3.66 fF.

Conductance of silicon:

$${G}_{si} = πσ / ln ( \frac{d}{2 a} + ( \sqrt{\frac{{d}^{2}}{2 {a}^{2}} - 1} ) ) = 39.61 Ω - m ( per unit length ) , \\ where 2 a = {D}_{TSV} .$$

Assuming σ=10Ω−cm which is the resistivity for silicon. Therefore, G_{Sil}=3.565 m/Ω.

Capacitance of SiO₂ around via:

$${C}_{ox via} = \frac{4 {ɛ}_{0} {ɛ}_{r} {t}_{si} ( {r}_{via} - {t}_{ox} )}{{t}_{ox}} = 5.36 pF , where {t}_{si} = {h}_{TSV} ; {r}_{via} = {D}_{TSV} / 2.$$

Surface SiO₂ and fringing capacitance between two via

$${C}_{ox} = {( ( \frac{2}{{C}_{ox \_ via}} + {( \frac{{ɛ}_{0} {ɛ}_{r} A}{d} )}^{- 1} ) )}^{- 1} = 4.21 fF .$$

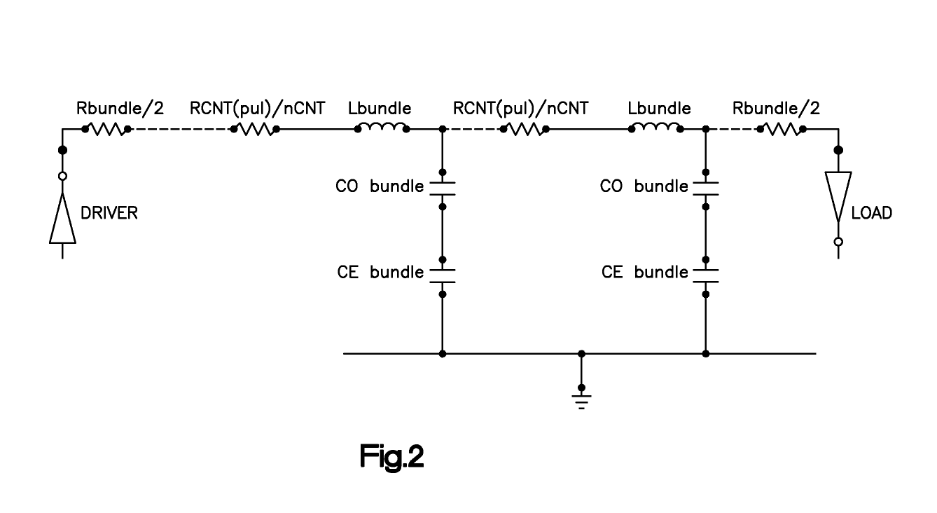

Referring now to FIG. 2, there is illustrated an equivalent electrical model of ST-CNT. The equivalent electrical model of the TSV shown in FIG. 1A, considers a set of specifications to calculate the parasitic values and obtain the equivalent electrical model. Because SW-CNT is used as a filler material in TSV, it would replace the Rᵥᵢₐ and Lᵥᵢₐ in FIG. 1A with R_{bundle}/2, R_{CNT(PUL)/nCNT} and L_{bundle}. It will also have other parasitic capacitances such as quantum capacitance (C_{Q}) and electrostatic capacitance (C_{E}) as shown in FIG. 2.

With reference to FIG. 2, a height of the CNT (h_{CNT}=h_{TSV}) may be 90 μm, a diameter of each individual CNT (d_{CNT})=1 nm, a distance of CNT to ground plane (γ)=100 μm, λ_{CNT} (typical mean free path of electrons in CNT)=1.6×10⁻⁶ μm, a number of CNT in the bundle (n_{CNT})=37522 which is approximated by calculating the area of the via and using the diameter of the CNT.

Resistance of SW-CNT

$${R}_{Bundle} = \frac{{R}_{F}}{{η}_{CNT}} where {R}_{F} = \frac{h}{4 {e}^{2}} = 6.45 k Ω ,$$

is the fundamental resistance of the CNT as described earlier, where h is the Planck's constant and e is electronic charge. Since the length of CNT>typical mean free path of electrons,

$${R}_{CNT} = \frac{{R}_{F} {h}_{CNT}}{{λ}_{CNT}} = 362.81 k Ω ,$$

this takes care of the scattering occurring in the CNT, as described above.

Inductance of SW-CNT

Overall inductance of the bundle may be determined according to the relationship

$${L}_{Bundle} = \frac{{L}_{CNT}}{{η}_{CNT}}$$

and L_{CNT}=L_{M}+L_{K}, where L_{M} is the magnetic inductance component and L_{K} is the kinetic inductance component. Since, the length of λ_{CNT}>CNT, L_{K} may be neglected and the total inductance just comprises L_{M}. Accordingly,

$${L}_{CNT} = {L}_{M} = \frac{μ}{2 π} ln ( \frac{y}{{d}_{CNT}} )$$

and correspondingly L_{Bundle}=5.58 fH.

Capacitance of SW-CNT

The quantum capacitance of the bundle is (C_{Q(Bundle)})=C_{Q}·n_{CNT}, where

$${C}_{Q} ( p . u . l ) = \frac{2 {e}^{2}}{{hv}_{F}} = 100 Af / μm .$$

Using corresponding values the following may be determined, C_{bundle}=0.3377 fF assuming v_{F} as the typical Fermi velocity of electrons in the carbon nanotube is 8×10⁵ m/s.

Electrostatic capacitance of the bundle is given by the following relationship:

$${C}_{E ( Bundle )} ( p . u . l ) = 2 {C}_{En} + \frac{( {n}_{w} - 2 )}{2} {C}_{Ef} + \frac{3 ( {n}_{H} - 2 )}{5} \cdot {C}_{En} ,$$

where C_{En} and C_{Ef} are the parallel plate capacitances of isolated SW-CNT with respect to near and far neighboring interconnects respectively.

Now the expression of

$${C}_{En} ( p . u . l ) = \frac{2 πɛ}{ln ( \frac{{D}_{TSV}}{{d}_{CNT}} )} = 18.58 pF ,$$

where D_{TSV} is the diameter of the via and d_{CNT} is the diameter of a single SW-CNT. Similarly, the expression of

$${C}_{En} ( p . u . l ) = \frac{2 πɛ}{ln ( \frac{2 {D}_{TSV}}{{d}_{CNT}} )} = 17.39 pF ,$$

where n_{w} and n_{H} are the number of nanotubes across width and length respectively. A circular via may be used for modeling purposes, thus n_{w}=n_{H}\sqrt{n_{CNG}}. Using the above values in equation (i), and incorporating length of CNT, C_{E(Bundle)}=0.346 pF.

Results and Simulations

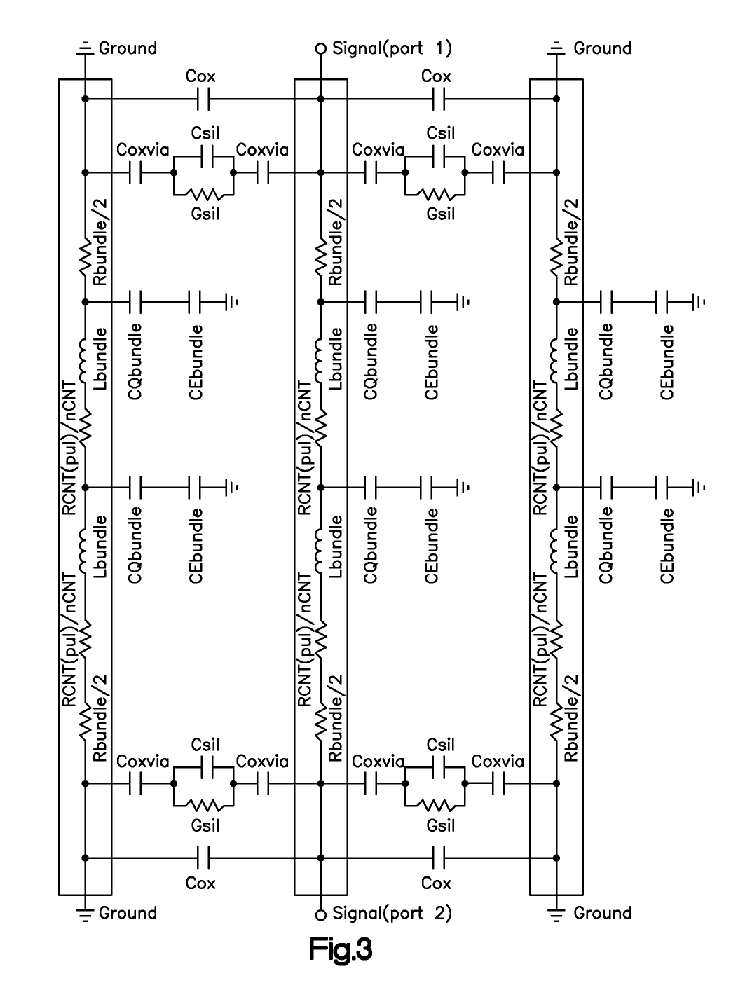

With reference to FIG. 3, there is illustrated an equivalent electrical model of a SW-CNT TSV. For simulation purposes, four different case studies were performed with practically achieved limits of via geometry and density of CNT bundles in accordance with the model of FIG. 3. This presents a realistic picture of performance of CNT-based TSV interconnects at high frequencies. Parameters for the four different case studies including parasitics, via dimensions and number of CNT bundles are below in Table 1.

TABLE 1

| Via | Number of | R_{TSV} | L_{TSV} | Cₛᵢ | Gₛᵢ | ESL | ESR | C_{Q bundle} | C_{E bundle} |
|---|---|---|---|---|---|---|---|---|---|
| Dimensions | bundles | (Ω) | (fH) | (fF) | (kΩ) | (pH) | (μΩ) | (fF) | (pF) |
| hᵥᵢₐ = 90 μm | 37522 | 9.83 | 5.580 | 3.661 | 0.211 | 12.755 | 110.36 | 0.3370 | 0.3460 |
| dᵥᵢₐ = 75 μm | | | | | | | | | |
| d_{CNT} = 1 nm | | | | | | | | | |
| hᵥᵢₐ = 90 μm | 45000 | 8.16 | 4.660 | 3.661 | 0.211 | 12.755 | 110.36 | 0.4050 | 0.3790 |
| dᵥᵢₐ = 75 μm | | | | | | | | | |
| d_{CNT} = 1 nm | | | | | | | | | |
| hᵥᵢₐ = 90 μm | 100 | 427.5 | 0.002 | 3.661 | 0.211 | 12.755 | 110.36 | 0.0009 | 0.0104 |
| dᵥᵢₐ = 75 μm | | | | | | | | | |
| d_{CNT} = 1 nm | | | | | | | | | |
| hᵥᵢₐ = 15 μm | 18761 | 3.56 | 0.480 | 0.122 | 3.430 | 10.701 | 206.50 | 0.0280 | 0.0610 |
| dᵥᵢₐ = 3 μm | | | | | | | | | |
| d_{CNT} = 2 nm | | | | | | | | | |

In a first study, the height and diameter of the via are 90 μm and 75 μm, respectively, and the distance of separation between the vias is 100 μm. The distance between the CNT bundle and ground plane is 100 μm, The diameter of each SW-CNT is 1 nm and the number of SW-CNTs in one bundle is 37522. Since all the CNTs in the bundle are not always conducting, only a small percentage of the total CNTs present are conducting in the TSV. The S11 measurements show that the input port reflection loss at a frequency of 4 GHz for Cu-TSV is −6.43 dBm and that for SW-CNT TSV is −19.15 dBm. The S21 value of the output port transmission loss at a frequency of 4 GHz for Cu-TSV is −43.33 dBm and that for SW-CNT TSV is −4.67 dBm.

From these results, it can now be realized that SW-CNT has a very low input reflection loss and transmission loss when compared to a Cu-TSV. The Time Domain Reflectometry (TDR) measurements show that the rise time for SW-CNT is 150.5 psec when compared to the Cu-TSV, which gives a rise time of 600 psec. This decreases the time delay in SW-CNT TSV and also the eye diagram provides better width and height of the eye when compared to Cu-TSV considering at a 1 Gbps signal.

In a second study, the same dimensions for the TSV and SW-CNT are used, but the number of conducting CNTs in the bundle is increased to 45000 to determine how the change in parasitic values in the electrical model will affect the performance of SW-CNT TSV. The S11 measurements show that the input port reflection loss at a frequency of 4 GHz for Cu-TSV is −6.43 dBm and that for SW-CNT TSV is −17.45 dBm. The S21 measurements show that the output port transmission loss at a frequency of 4 GHz for Cu-TSV is −43.33 dBm and that for SW-CNT TSV is −5.37 dBm. These results reveal that increasing the number of CNTs increases the parasitic values, and thereby increases the input and output port losses. Even though increasing the number of CNTs decreases the resistance, it causes an increase in the quantum and electrostatic capacitances of the SW-CNT TSV. The TDR and eye diagram analysis showed similar results as in the previous case.

In a third study, the same dimensions for the TSV are used, but the diameter of CNT is changed to 2 nm. The number of conducting CNTs in the bundle is reduced to 100 to see how the change in parasitic values in the electrical model will affect the performance of SW-CNT TSV. The S11 measurements show that the input port reflection loss at a frequency of 4 GHz for Cu-TSV is −6.43 dBm and that for SW-CNT TSV is −6.15 dBm. The S21 measurements show that the output port transmission loss at a frequency of 4 GHz for Cu-TSV is −43.33 dBm and that for SW-CNT TSV is −42.87 dBm. These results reveal that decreasing the number of CNTs decreases the parasitic values, and thereby increases the input and output port losses. Since a low number of CNTs increases the resistance, it causes an increase in the resistances and inductances of the SW-CNT TSV. The TDR and eye diagram analysis showed similar results as in the previous cases. The above results shows that even with a very small amount of CNTs in the bundle as low as 100, the performance of a copper TSV may be achieved, hence simple fabrication techniques may be used to realize the SW-CNT TSV.

In a fourth study, observing the results in the previous case studies an optimum set of TSV and SW-CNT dimensions is used to achieve high performance results. The height and diameter of the via are 15 μm and 3 μm, respectively, and the distance of separation between the vias to be 20 μm. The distance between the CNT bundle and ground plane is 20 μm. The diameter of each SW-CNT is 1 nm and the number of SW-CNTs in one bundle is 18761. The S11 measurements show that the input port reflection loss at a frequency of 4 GHz for Cu-TSV is −0.35 dBm and that for SW-CNT TSV is −24.21 dBm. The S21 measurements show that the output port transmission loss at a frequency of 4 GHz for Cu-TSV is −17.5 dBm and that for SW-CNT TSV is −0.73 dBm.

From these results, in can be inferred that SW-CNT has a very low input reflection loss and transmission loss when compared to a Cu-TSV. The TDR measurements show that the rise time for SW-CNT is 44 psec when compared to the Cu-TSV which gives a rise time of 59 psec, this decreases the time delay in SW-CNT TSV and also the eye diagram gives better width and height of the eye when compared to Cu-TSV considering a 1 Gbps signal.

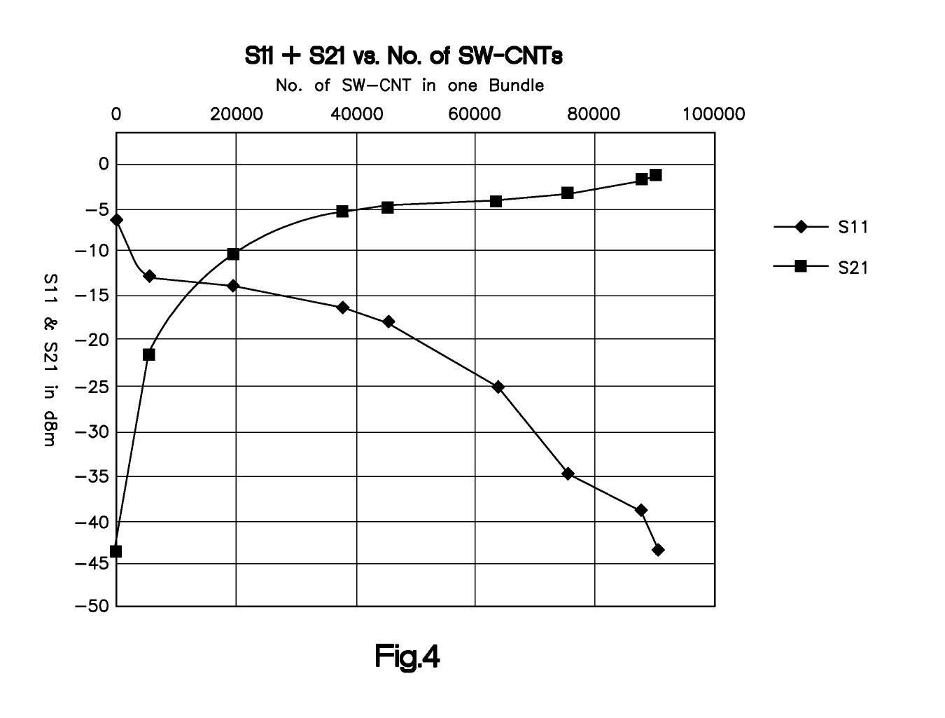

FIG. 4 illustrates S11 and S21 parameters of SW-CNT TSV vs. a number of CNTs in one bundle. S11 and S21 is measured at a frequency of 4 GHz considering high frequency applications. The S21 decreases with increase in number of CNTs thus giving low transmission loss; S11 increases with increase in number of CNTs giving low input port reflection losses shown in FIG. 4.

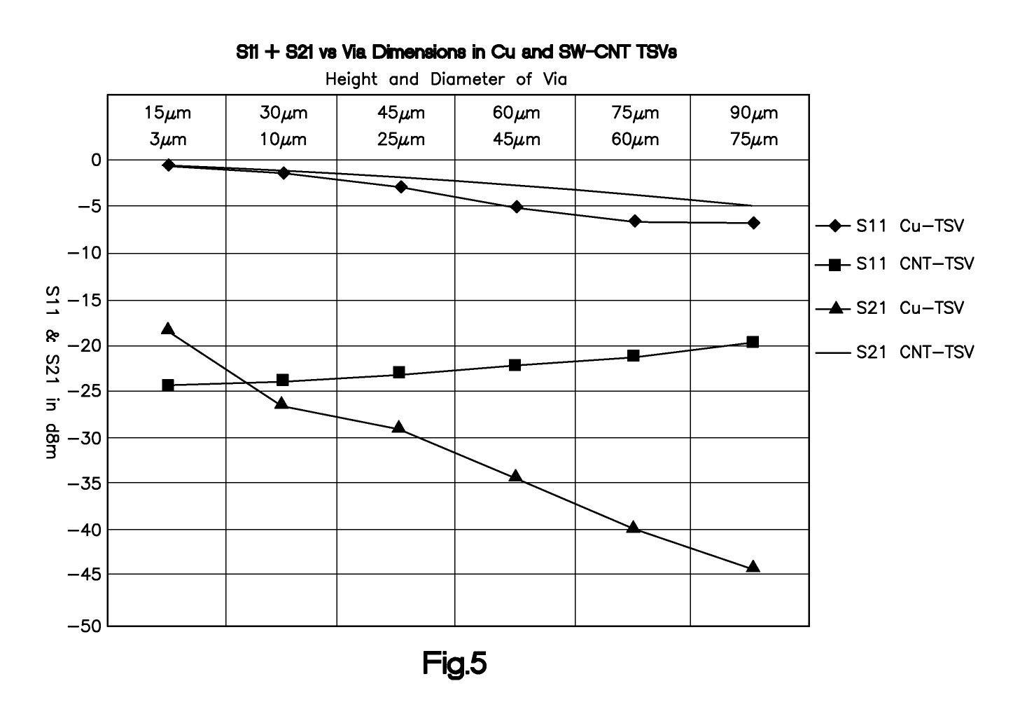

FIGS. 5 S11 and S21 parameters of both Cu-TSV and SW-CNT TSV vs. change in via dimensions. As the via dimension increases, the SII decreases in Cu-TSV but increases in SW-CNT thus affecting the performance of SW-CNT TSV. For S21 as the via dimensions are increased on both the Cu and SW-CNT TSVs performance decreases as shown in FIG. 8.

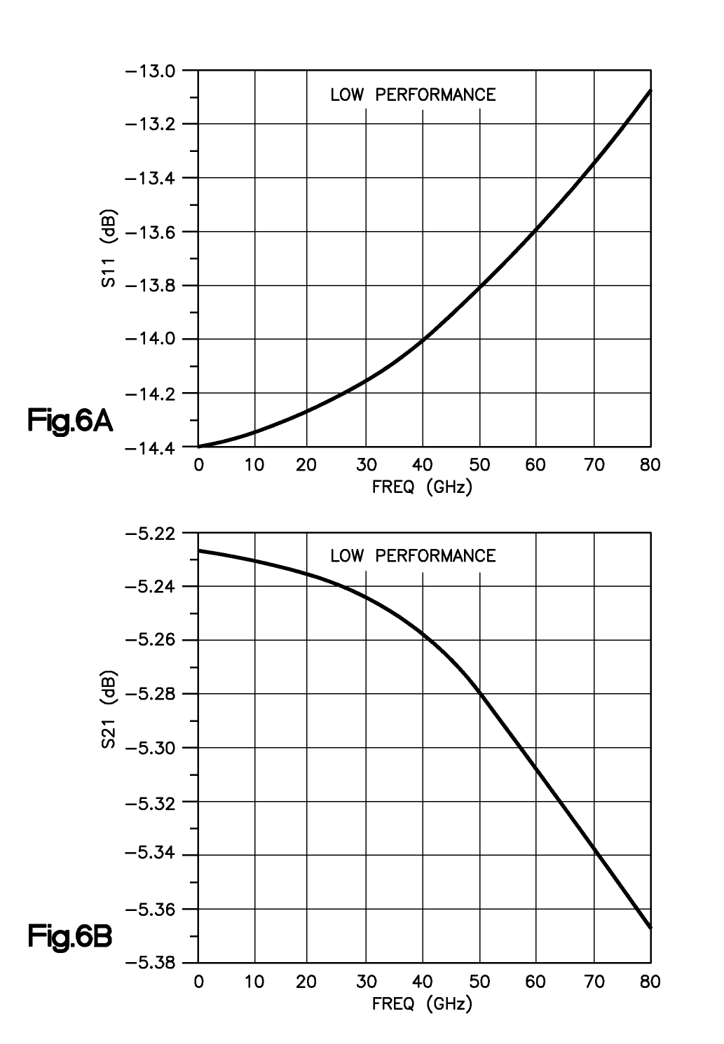

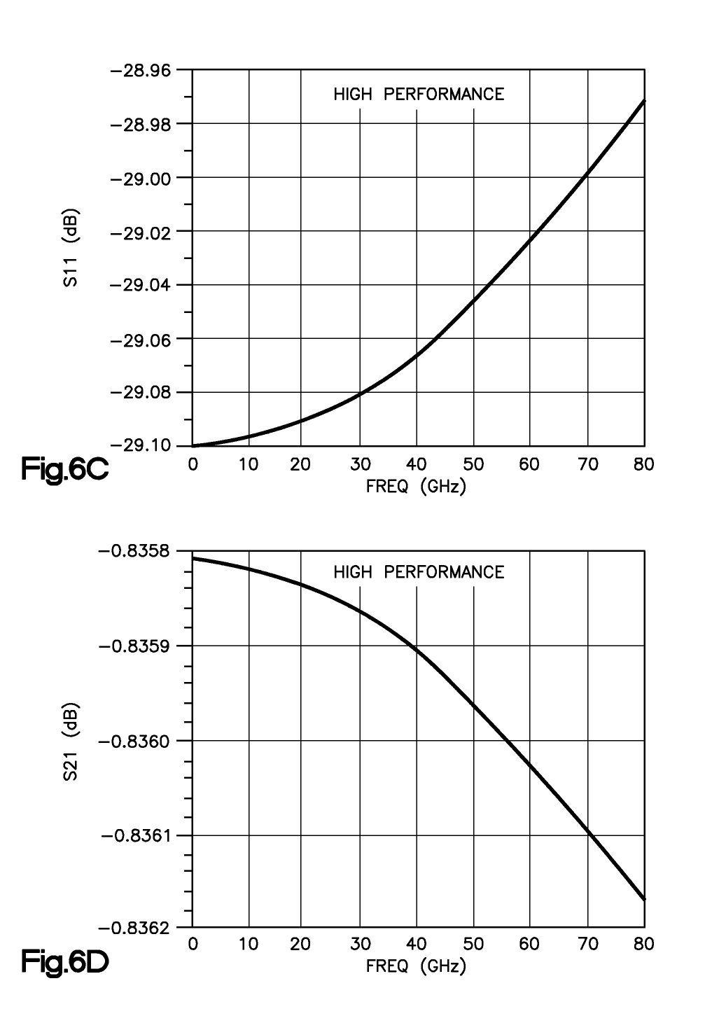

FIGS. 6A-6D illustrates S11 and S21 for low-performance CNT-TSV and S11 and S21 for high-performance CNT-TSV. The low performance CNT-TSV was considered as a TSV filled with high density CNT bundles (n=45000) with via height=90 μm and diameter=75 μm (the second study above). The reflection losses (S11) in this case are −13.6 dB in 60 GHz range, corresponding output port transmission is −5.31 dB in that frequency range as shown in FIGS. 6A and 6B.

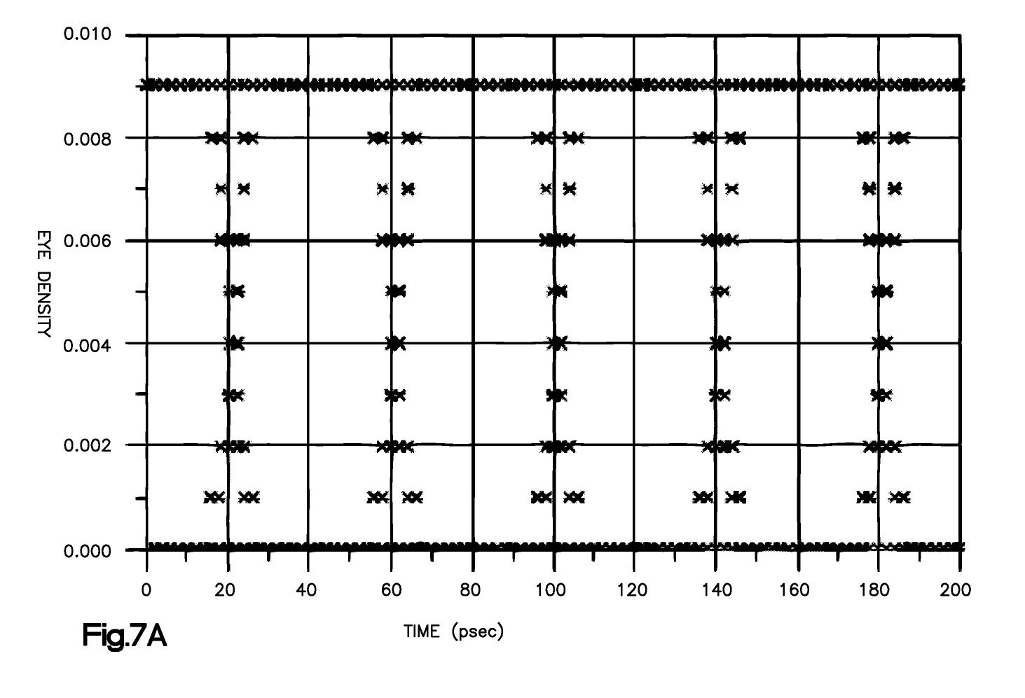

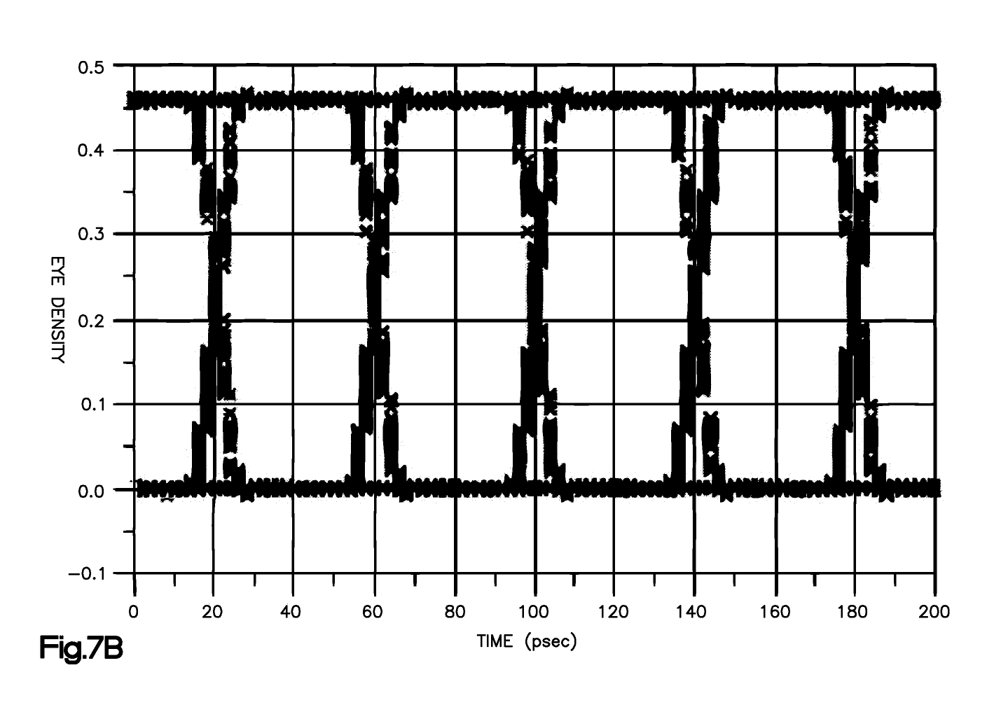

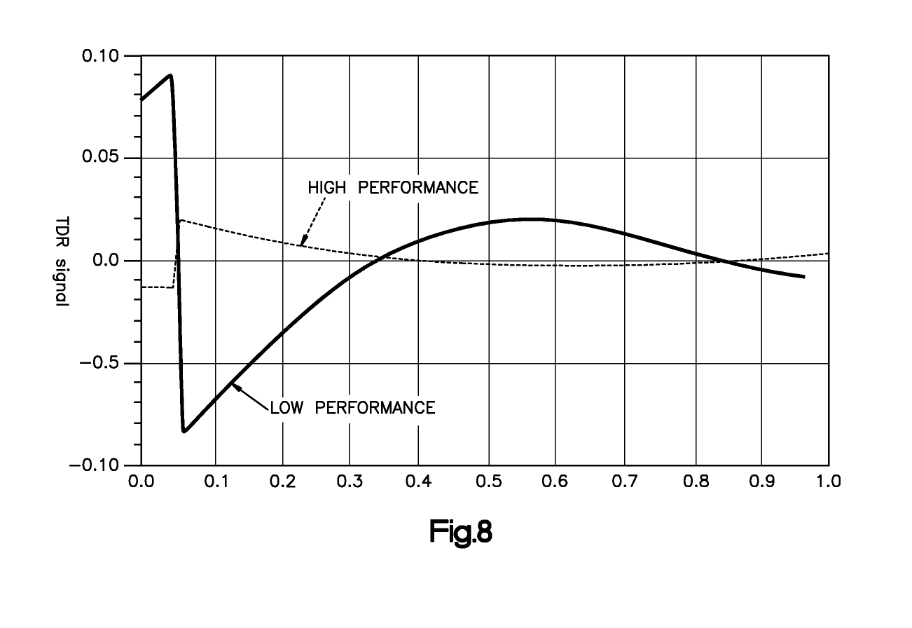

Eye diagram analysis and TDR measurements to perform time domain simulation shows low electrical throughput. In the eye diagram analysis, as shown in FIG. 7A, eye height of 0.009. An eye width of 20 psec was found for a 25 Gbps transmission rate. From FIG. 7A it can be inferred that the eye density is lower and that there is overlap between different cycles of data transmission resulting in highly distorted output signal.

Comparing this to the fourth case of via dimensions with via height=15 μm, via diameter=3 μm and other variables such as density of CNT bundle (=18761) and diameter of CNT (=2 nm) that have been optimized, a high signal throughput is attainable. As shown in FIG. 6C, input port reflection (S11) was found to be as low as −23.03 dB, while at the same time output port transmission was of the order of −0.083 dB, as shown in FIG. 6D. Eye diagram analysis with 25 Gbps signal leads to high transmission rates, as indicated by an eye width of 40 psec and an eye height of 0.45 in FIG. 7B.

A comparative TDR analysis of the two contrasting cases is shown in FIG. 8. In the low-performance case, the magnitude of delay was 0.09, whereas for the high-performance case it was 0.02, which indicates better signal throughput at a high transmission rate. It can be inferred that signal throughput and transmission is much better in the second case than in the first one.

Thus, in view of the above, it is now understood that CNT-based TSV technology, through effective via design and overcoming fabrication challenges related to CNT growth in a TSV, has the potential to become the technology of the future. 3D integration of heterogeneous technologies such as RF, analog and digital for high-frequency applications can then be realized with a high performance-to-cost ratio for these CNT-based TSV interconnects. In addition, an optimum range for via dimensions, SW-CNT TSV dimensions and the number of CNTs in the bundle has been described.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed:

1. A semiconductor chip comprising:
a semiconductor chip body formed from silicon;
a carbon nanotube through silicon via that passes through the semiconductor chip body and contacts a metal layer at at least one end; and
an insulating layer that surrounds the carbon nanotube through silicon via.

2. The semiconductor chip as recited in claim 1, wherein the insulating layer is formed from silicon dioxide.

3. The semiconductor chip as recited in claim 1, wherein the carbon nanotube through silicon via is formed as carbon nanotube bundles.

4. The semiconductor chip as recited in claim 3, wherein a height of the carbon nanotube through silicon via is approximately 90 μm.

5. The semiconductor chip as recited in claim 3, wherein a diameter of the carbon nanotube through silicon via is approximately 75 μm.

6. The semiconductor chip as recited in claim 3, a diameter of each carbon nanotube is approximately 1 nm.

7. The semiconductor chip as recited in claim 3, wherein the carbon nanotube through silicon via is formed from approximately 18761 bundles.

8. The semiconductor chip as recited in claim 1, wherein the insulating layer has a thickness of approximately 0.1 μm.

9. The semiconductor chip as recited in claim 1, wherein the semiconductor chip is provided as part of a three-dimensional large-scale integration package.

10. The semiconductor chip as recited in claim 9, wherein the carbon nanotube through silicon via is used as an interconnect within the three-dimensional large-scale integration package.

11. The semiconductor chip as recited in claim 10, wherein the three-dimensional large-scale integration package is provided within a RF application having a frequency of between 20 GHz and 80 GHz.

12. An integrated circuit (IC) through-silicon via (TSV) structure comprising:
a plurality of carbon nanotube bundles disposed within an integrated circuit package;
and an insulating layer that surrounds the plurality carbon nanotube bundles.

13. The IC as recited in claim 12, wherein a height of the carbon nanotube bundles is approximately 90 μm.

14. The IC as recited in claim 12, wherein a diameter of the TSV is approximately 75 μm.

15. The IC as recited in claim 12, a diameter of each carbon nanotube within the plurality of carbon nanotube bundles is approximately 1 nm.

16. The IC as recited in claim 12, wherein a number of carbon nanotube bundles is approximately 18761.

17. The IC as recited in claim 12, wherein the insulating layer has a thickness of approximately 0.1 μm.

18. A integrated circuit package system comprising:
an integrated circuit die having carbon nanotube through silicon vias each surrounded by an insulating layer, the carbon nanotube through silicon vias each contacting a metallic pad at each of an upper and lower surface of the integrated circuit,
wherein the integrated circuit die is adapted to be assembled into three-dimensional package using the carbon nanotube through silicon vias as interconnects.

19. The system as recited in claim 18, wherein the metallic pad is made from copper.

20. The system as recited in claim 18, wherein the carbon nanotube through silicon vias are provided as carbon nanotube bundles, and wherein each carbon nanotube has a diameter of approximately 1 nm.
